(19) United States
(12) Patent Application Publication
(10) Pub. No.: US 2023/0307369 A1
(43) Pub. Date: Sep. 28, 2023

(54) SEMICONDUCTOR MEMORY DEVICE AND METHOD FOR MANUFACTURING SEMICONDUCTOR MEMORY DEVICE

(71) Applicant: Kioxia Corporation, Tokyo (JP)

(72) Inventors: Nobuhito Ichiki, Yokkaichi Mie (JP); Keisuke Nakatsuka, Kobe Hyogo (JP); Shinya Arai, Yokkaichi Mie (JP); Koichi Sakata, Yokkaichi Mie (JP); Susumu Hashimoto, Yokkaichi Mie (JP)

(73) Assignee: Kioxia Corporation, Tokyo (JP)

(21) Appl. No.: 17/890,377

(22) Filed: Aug. 18, 2022

(30) Foreign Application Priority Data
Mar. 24, 2022 (JP) 2022-048800

(51) Int. Cl. H01L 23/535; H01L 23/532; H01L 27/11556; H01L 27/11582

(52) U.S. Cl. CPC H01L 23/535; H01L 23/53257; H01L 27/11556; H01L 27/11582

(57) ABSTRACT

A semiconductor memory device includes a first wiring, a second wiring, a memory pillar, a semiconductor layer, and a contact plug. The second wiring is provided above the first wiring in a first direction. The memory pillar penetrating at least one of a portion of the first wiring or a portion of the second wiring in the first direction. The semiconductor layer extends in the first direction provided in the memory pillar. The contact plug contains a metal and has a lower surface provided in the memory pillar, and the lower surface is in contact with the semiconductor layer below an upper surface of the second wiring.

### CROSS-REFERENCE TO RELATED APPLICATION(S)

This application is based upon and claims the benefit of priority from Japanese Patent Application No. 2022-048800, filed Mar. 24, 2022, the entire contents of which are incorporated herein by reference.

### FIELD

Embodiments described herein relate generally to a semiconductor memory device and a method for manufacturing a semiconductor memory device.

### BACKGROUND

In general, in a semiconductor memory device (e.g., a NAND flash memory), the amount of holes required at the time of data erasing is increasing along with high integration.

### DESCRIPTION OF THE DRAWINGS

FIG. 1 is a block diagram showing a configuration example of a memory system using a semiconductor memory device according to an embodiment.

FIG. 2 is a block diagram showing a configuration example of a nonvolatile memory according to the embodiment.

FIG. 3 is a diagram showing a configuration example of a block of a memory cell array having a three-dimensional structure.

FIG. 4A is a cross-sectional view of a part of a region of a memory cell array having a three-dimensional structure.

FIG. 4B is another cross-sectional view of a part of a region of a memory cell array having a three-dimensional structure.

FIG. 4C is another cross-sectional view of a part of a region of a memory cell array having a three-dimensional structure.

FIG. 4D is another cross-sectional view of a part of a region of a memory cell array having a three-dimensional structure.

FIG. 5A is a cross-sectional view of the memory cell array showing an example of a manufacturing process of the memory cell array shown in FIG. 4A.

FIG. 5B is a cross-sectional view of the memory cell array showing the example of the manufacturing process of the memory cell array shown in FIG. 4A.

FIG. 5C is a cross-sectional view of the memory cell array showing the example of the manufacturing process of the memory cell array shown in FIG. 4A.

FIG. 5D is a cross-sectional view of the memory cell array showing the example of the manufacturing process of the memory cell array shown in FIG. 4A.

FIG. 5E is a cross-sectional view of the memory cell array showing the example of the manufacturing process of the memory cell array shown in FIG. 4A.

FIG. 5F is a cross-sectional view of the memory cell array showing the example of the manufacturing process of the memory cell array shown in FIG. 4A.

FIG. 5G is a cross-sectional view of the memory cell array showing the example of the manufacturing process of the memory cell array shown in FIG. 4A.

FIG. 5H is a cross-sectional view of the memory cell array showing the example of the manufacturing process of the memory cell array shown in FIG. 4A.

FIG. 6A is a cross-sectional view of the memory cell array showing another example of the manufacturing process of the memory cell array shown in FIG. 4A.

FIG. 6B is a cross-sectional view of the memory cell array showing the other example of the manufacturing process of the memory cell array shown in FIG. 4A.

FIG. 6C is a cross-sectional view of the memory cell array showing the other example of the manufacturing process of the memory cell array shown in FIG. 4A.

FIG. 6D is a cross-sectional view of the memory cell array showing the other example of the manufacturing process of the memory cell array shown in FIG. 4A.

FIG. 6E is a cross-sectional view of the memory cell array showing the other example of the manufacturing process of the memory cell array shown in FIG. 4A.

FIG. 6F is a cross-sectional view of the memory cell array showing the other example of the manufacturing process of the memory cell array shown in FIG. 4A.

FIG. 6G is a cross-sectional view of the memory cell array showing the other example of the manufacturing process of the memory cell array shown in FIG. 4A.

FIG. 6H is a cross-sectional view of the memory cell array showing the other example of the manufacturing process of the memory cell array shown in FIG. 4A.

FIG. 6I is a cross-sectional view of the memory cell array showing the other example of the manufacturing process of the memory cell array shown in FIG. 4A.

FIG. 6J is a cross-sectional view of the memory cell array showing the other example of the manufacturing process of the memory cell array shown in FIG. 4A.

FIG. 6K is a cross-sectional view of the memory cell array showing the other example of the manufacturing process of the memory cell array shown in FIG. 4A.

FIG. 6L is a cross-sectional view of the memory cell array showing the other example of the manufacturing process of the memory cell array shown in FIG. 4A.

FIG. 7A is a cross-sectional view of the memory cell array showing an example of a manufacturing process of the memory cell array shown in FIG. 4B.

FIG. 7B is a cross-sectional view of the memory cell array showing the example of the manufacturing process of the memory cell array shown in FIG. 4B.

FIG. 7C is a cross-sectional view of the memory cell array showing the example of the manufacturing process of the memory cell array shown in FIG. 4B.

FIG. 7D is a cross-sectional view of the memory cell array showing the example of the manufacturing process of the memory cell array shown in FIG. 4B.

FIG. 7E is a cross-sectional view of the memory cell array showing the example of the manufacturing process of the memory cell array shown in FIG. 4B.

FIG. 7F is a cross-sectional view of the memory cell array showing the example of the manufacturing process of the memory cell array shown in FIG. 4B.

FIG. 7G is a cross-sectional view of the memory cell array showing the example of the manufacturing process of the memory cell array shown in FIG. 4B.

FIG. 7H is a cross-sectional view of the memory cell array showing the example of the manufacturing process of the memory cell array shown in FIG. 4B.

FIG. 7I is a cross-sectional view of the memory cell array showing the example of the manufacturing process of the memory cell array shown in FIG. 4B.

FIG. 7J is a cross-sectional view of the memory cell array showing the example of the manufacturing process of the memory cell array shown in FIG. 4B.

FIG. 7K is a cross-sectional view of the memory cell array showing the example of the manufacturing process of the memory cell array shown in FIG. 4B.

FIG. 7L is a cross-sectional view of the memory cell array showing the example of the manufacturing process of the memory cell array shown in FIG. 4B.

FIG. 8A is a cross-sectional view of the memory cell array showing an example of a manufacturing process of the memory cell array shown in FIG. 4C.

FIG. 8B is a cross-sectional view of the memory cell array showing the example of the manufacturing process of the memory cell array shown in FIG. 4C.

FIG. 8C is a cross-sectional view of the memory cell array showing the example of the manufacturing process of the memory cell array shown in FIG. 4C.

FIG. 8D is a cross-sectional view of the memory cell array showing the example of the manufacturing process of the memory cell array shown in FIG. 4C.

FIG. 9A is a cross-sectional view of the memory cell array showing an example of a manufacturing process of the memory cell array shown in FIG. 4D.

FIG. 9B is a cross-sectional view of the memory cell array showing the example of the manufacturing process of the memory cell array shown in FIG. 4D.

FIG. 9C is a cross-sectional view of the memory cell array showing the example of the manufacturing process of the memory cell array shown in FIG. 4D.

FIG. 9D is a cross-sectional view of the memory cell array showing the example of the manufacturing process of the memory cell array shown in FIG. 4D.

FIG. 10 is a top view showing an example of a processed shape of an insulating layer in the memory cell arrays shown in FIGS. 4A to 4D.

FIG. 11 is a top view and a cross-sectional view showing an example of a highly integrated structure to which the manufacturing process of the embodiment is applied.

FIG. 12 is a top view and a cross-sectional view showing another example of the highly integrated structure to which the manufacturing process of the embodiment is applied.

### DETAILED DESCRIPTION

Embodiments provide a semiconductor memory device and a method for manufacturing a semiconductor memory device that can increase a supply amount of holes at the time of data erasing.

In general, according to one embodiment, the semiconductor memory device includes a first wiring, a second wiring, a memory pillar, a semiconductor layer, and a contact plug. The second wiring is provided above the first wiring in a first direction. The memory pillar penetrating at least one of a portion of the first wiring or a portion of the second wiring in the first direction. The semiconductor layer extends in the first direction provided in the memory pillar. The contact plug contains a metal and has a lower surface provided in the memory pillar, and the lower surface is in contact with the semiconductor layer below an upper surface of the second wiring.

Hereinafter, embodiments will be described with reference to the drawings.

### First Embodiment

### 1. Configuration

### 1-1. Configuration of Memory System

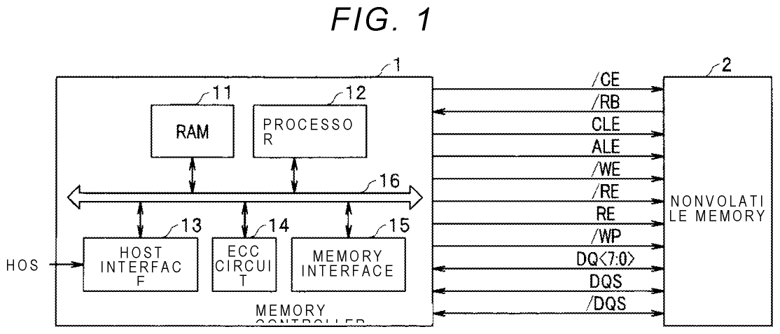

FIG. 1 is a block diagram showing a configuration example of a memory system using a semiconductor memory device according to an embodiment. The memory system according to the embodiment includes a memory controller 1 and a nonvolatile memory 2 serving as the semiconductor memory device. The memory system is connectable to a host. The host is, for example, a personal computer or a mobile terminal.

The nonvolatile memory 2 is a memory that stores data in a nonvolatile manner, and includes, for example, a NAND memory (a NAND flash memory). The nonvolatile memory 2 is, for example, a NAND memory including memory cells capable of storing 3 bits per memory cell, that is, a NAND memory of 3 bits/Cell (TLC: triple level cell). The nonvolatile memory 2 may be a NAND memory capable of storing a plurality of bits such as 1 bit/Cell, 2 bits/Cell, 4 bits/Cell, or more. Generally, the nonvolatile memory 2 includes a plurality of memory chips.

The memory controller 1 controls writing of data to the nonvolatile memory 2 in accordance with a write request from the host. In addition, the memory controller 1 controls reading of data from the nonvolatile memory 2 in accordance with a read request from the host. Signals including a chip enable signal /CE, a ready and busy signal /RB, a command latch enable signal CLE, an address latch enable signal ALE, a write enable signal /WE, read enable signals RE and /RE, a write protect signal /WP, a data signal DQ<7:0>, and data strobe signals DQS and /DQS are transmitted and received between the memory controller 1 and the nonvolatile memory 2.

A signal with a symbol “/” attached to the beginning indicates an active low or negative logic. That is, a signal with no symbol “/” attached to the beginning is active when the signal is at an “H” state, whereas a signal with the symbol “/” attached to the beginning is active when the signal is at an “L” state.

For example, the nonvolatile memory 2 and the memory controller 1 are each formed as a semiconductor chip (hereinafter, also simply referred to as a “chip”).

The chip enable signal /CE is a signal for selecting and enabling a specific memory chip of the nonvolatile memory 2. The ready and busy signal /RB is a signal for indicating whether the nonvolatile memory 2 is in a ready state (a state in which a command from the outside can be received) or in a busy state (a state in which a command from the outside cannot be received). The memory controller 1 can grasp the state of the nonvolatile memory 2 by receiving the signal /RB. The command latch enable signal CLE is a signal indicating that the signal DQ<7:0>is a command. The command latch enable signal CLE enables a command transmitted as the signal DQ to be latched in a command register in the selected memory chip of the nonvolatile memory 2. The address latch enable signal ALE is a signal indicating that the signal DQ<7:0> is an address. The address latch enable signal ALE enables an address transmitted as the signal DQ to be latched in an address register in the selected memory chip of the nonvolatile memory 2. The write enable signal /WE is a signal for capturing a received signal into the nonvolatile memory 2, and is asserted every time a command, an address, and data are received by the memory controller 1. When the write enable signal /WE is at the “L (low)” state, the nonvolatile memory 2 is instructed to capture the signal DQ<7:0>.

The read enable signals RE and /RE are signals for the memory controller 1 to read data from the nonvolatile memory 2. For example, the read enable signals RE and /RE are used to control an operation timing of the nonvolatile memory 2 when the signal DQ<7:0> is output. The write protect signal /WP is a signal for instructing the nonvolatile memory 2 to prohibit data writing and erasing. The signal DQ<7:0> is the data transmitted and received between the nonvolatile memory 2 and the memory controller 1, and includes a command, an address, and data. The data strobe signals DQS and /DQS are signals for controlling input and output timings of the signal DQ<7:0>.

The memory controller 1 includes a random access memory (RAM) 11, a processor 12, a host interface 13, an error check and correct (ECC) circuit 14, and a memory interface 15. The RAM 11, the processor 12, the host interface 13, the ECC circuit 14, and the memory interface 15 are connected to one another via an internal bus 16.

The host interface 13 outputs, to the internal bus 16, a request, user data (write data), and the like that are received from the host. In addition, the host interface 13 transmits, to the host, user data read from the nonvolatile memory 2, a response from the processor 12, and the like.

The memory interface 15 controls, based on an instruction of the processor 12, processing of writing user data or the like to the nonvolatile memory 2 and processing of reading user data or the like from the nonvolatile memory 2.

The processor 12 integrally controls the memory controller 1. The processor 12 is, for example, a central processing unit (CPU) or a micro-processing unit (MPU). When the processor 12 receives a request from the host via the host interface 13, the processor 12 executes control in accordance with the request. For example, the processor 12 instructs the memory interface 15 to write user data and parity to the nonvolatile memory 2 in accordance with the request from the host. In addition, the processor 12 instructs the memory interface 15 to read the user data and the parity from the nonvolatile memory 2 in accordance with the request from the host.

The processor 12 determines, for the user data stored in the RAM 11, a storage region (a memory region) in the nonvolatile memory 2. The user data is stored in the RAM 11 via the internal bus 16. The processor 12 determines a memory region for data in units of pages (page data), which is a write unit. In the present description, user data stored in one page of the nonvolatile memory 2 is defined as unit data. The unit data is generally encoded by the ECC circuit 14 and is stored in the nonvolatile memory 2 as a code word. In the present embodiment, encoding is not necessary. The memory controller 1 may store the unit data in the nonvolatile memory 2 without encoding. FIG. 1 shows, as a configuration example, a configuration in which encoding is executed. When the memory controller 1 does not execute encoding, the page data is the same as the unit data. In addition, one code word may be generated based on one piece of unit data, or one code word may be generated based on divided data obtained by dividing the unit data. In addition, one code word may be generated using a plurality of pieces of unit data.

The processor 12 determines, for each piece of unit data, a memory region of the nonvolatile memory 2 as a write destination. A physical address is assigned to each memory region of the nonvolatile memory 2. The processor 12 manages, using the physical address, the memory region to which the unit data is written. The processor 12 designates the determined memory region (a physical address) and instructs the memory interface 15 to write the user data to the nonvolatile memory 2. The processor 12 manages a correspondence between the physical address and the logical address (the logical address managed by the host) of the user data. When the processor 12 receives, from the host, a read request including the logical address, the processor 12 specifies a physical address corresponding to the logical address, designates the physical address, and instructs the memory interface 15 to read the user data.

The ECC circuit 14 encodes the user data stored in the RAM 11 to generate a code word. In addition, the ECC circuit 14 decodes the code word read from the nonvolatile memory 2.

The RAM 11 temporarily stores the user data received from the host before the user data is stored in the nonvolatile memory 2, and temporarily stores the data read from the nonvolatile memory 2 before the data is transmitted to the host. The RAM 11 is, for example, a general-purpose memory such as a static random access memory (SRAM) or a dynamic random access memory (DRAM).

FIG. 1 shows a configuration example in which the memory controller 1 includes the ECC circuit 14 and the memory interface 15. The ECC circuit 14 may be provided in the memory interface 15. In addition, the ECC circuit 14 may be provided in the nonvolatile memory 2.

When a write request is received from the host, the memory system operates as follows. The processor 12 temporarily stores the data to be written in the RAM 11. The processor 12 reads the data stored in the RAM 11 and inputs the data to the ECC circuit 14. The ECC circuit 14 encodes the input data and inputs a code word to the memory interface 15. The memory interface 15 writes the input code word into the nonvolatile memory 2.

When a read request is received from the host, the memory system operates as follows. The memory interface 15 inputs a code word read from the nonvolatile memory 2 to the ECC circuit 14. The ECC circuit 14 decodes the input code word and stores decoded data in the RAM 11. The processor 12 transmits the data stored in the RAM 11 to the host via the host interface 13.

### 1-2. Configuration of Nonvolatile Memory

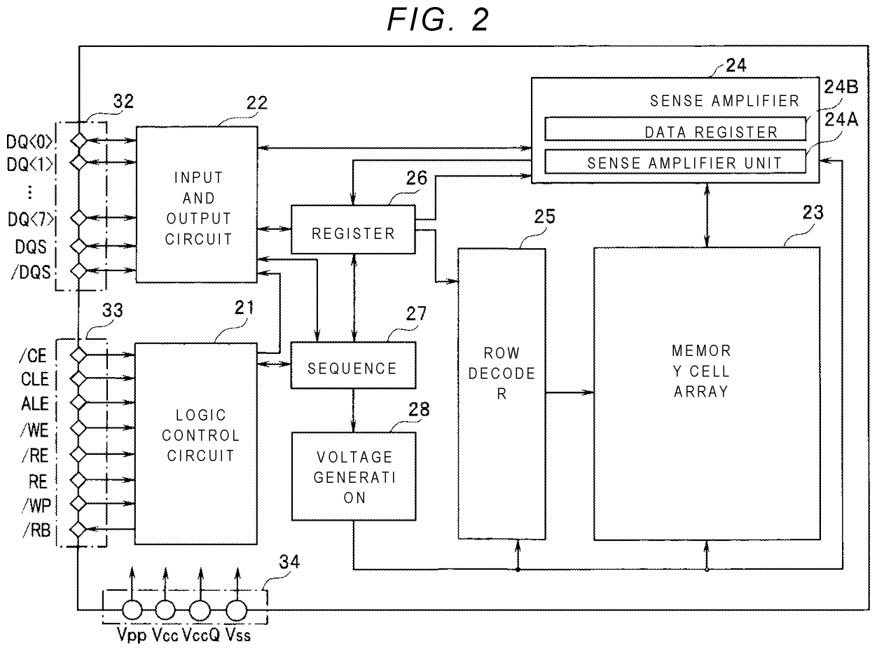

FIG. 2 is a block diagram showing a configuration example of a nonvolatile memory according to the embodiment. The nonvolatile memory 2 includes a logic control circuit 21, an input and output circuit 22, a memory cell array 23, a sense amplifier 24, a row decoder 25, a register 26, a sequencer 27, a voltage generation circuit 28, an input and output pad group 32, a logic control pad group 33, and a power input terminal group 34.

The memory cell array 23 includes a plurality of blocks BLK. Each of the plurality of blocks BLK includes a plurality of memory cell transistors (memory cells). In order to control voltages applied to the memory cell transistors, for example, a plurality of bit lines, a plurality of word lines, and a source line are disposed in the memory cell array 23. A specific configuration of the block BLK will be described later.

In order to transmit and receive signals including data to and from the memory controller 1, the input and output pad group 32 includes a plurality of terminals (pads) corresponding to the signal DQ<7:0> and the data strobe signals DQS and /DQS.

In order to transmit and receive signals to and from the memory controller 1, the logic control pad group 33 includes a plurality of terminals (pads) corresponding to the chip enable signal /CE, the command latch enable signal CLE, the address latch enable signal ALE, the write enable signal /WE, the read enable signals RE and /RE, the write protect signal /WP, and the ready and busy signal /RB.

In order to supply various operation power supplies to the nonvolatile memory 2 from the outside, the power input terminal group 34 includes a plurality of terminals to which power supply voltages Vcc, VccQ, Vpp and a ground voltage Vss are input. The power supply voltage Vcc, as an operation power supply, is a circuit power supply voltage generally applied from the outside, and for example, a voltage of about 3.3 V is input thereto. As the power supply voltage VccQ, for example, a voltage of 1.2 V is input. The power supply voltage VccQ is used when a signal is transmitted and received between the memory controller 1 and the nonvolatile memory 2.

The power supply voltage Vpp is a power supply voltage higher than the power supply voltage Vcc, and for example, a voltage of 12 V is input thereto. When data is written to or erased from the memory cell array 23, a high voltage of about 20 V is required. At this time, a desired voltage can be generated at a high speed and low power consumption by boosting the power supply voltage Vpp of about 12 V rather than boosting the power supply voltage Vcc of about 3.3 V by a booster circuit of the voltage generation circuit 28. The power supply voltage Vcc is a power supply that is normally supplied to the nonvolatile memory 2, and the power supply voltage Vpp is a power supply that is additionally and freely supplied in accordance with a use environment, for example.

The logic control circuit 21 and the input and output circuit 22 are connected to the memory controller 1 via a NAND bus. The input and output circuit 22 transmits and receives the signals DQ (for example, DQ0 to DQ7) to and from the memory controller 1 via the NAND bus.

The logic control circuit 21 receives, via the NAND bus, external control signals (for example, the chip enable signal /CE, the command latch enable signal CLE, the address latch enable signal ALE, the write enable signal /WE, the read enable signals RE and /RE, and the write protect signal /WP) from the memory controller 1. In addition, the logic control circuit 21 transmits the ready and busy signal /RB to the memory controller 1 via the NAND bus.

The input and output circuit 22 transmits and receives the signal DQ<7:0> and the data strobe signals DQS and /DQS to and from the memory controller 1. The input and output circuit 22 transfers, to the register 26, the command and the address in the signal DQ<7:0>. In addition, the input and output circuit 22 transmits and receives the write data and read data to and from the sense amplifier 24.

The register 26 includes a command register, an address register, and a status register. The command register temporarily stores a command. The address register temporarily stores an address. The status register temporarily stores data necessary for an operation of the nonvolatile memory 2. The register 26 includes, for example, an SRAM.

The sequencer 27 serving as a control unit receives the command from the register 26, and controls the nonvolatile memory 2 in accordance with a sequence based on the command.

The voltage generation circuit 28 receives a power supply voltage from the outside of the nonvolatile memory 2, and generates, using the power supply voltage, a plurality of voltages necessary for a write operation, a read operation, and an erase operation. The voltage generation circuit 28 supplies the generated voltages to the memory cell array 23, the sense amplifier 24, and the row decoder 25.

The row decoder 25 receives a row address from the register 26 and decodes the row address. The row decoder 25 selects a word line based on the decoded row address. Then, the row decoder 25 transfers, to a selected block, the plurality of voltages necessary for the write operation, the read operation, and the erase operation.

The sense amplifier 24 receives a column address from the register 26 and decodes the column address. The sense amplifier 24 includes a sense amplifier unit group 24A and a data register 24B. The sense amplifier unit group 24A is connected to the bit lines, and selects one of the bit lines based on the decoded column address. In addition, during reading of data, the sense amplifier unit group 24A detects and amplifies the data read from the memory cell transistor to the bit line. In addition, during writing of data, the sense amplifier unit group 24A transfers the write data to the bit line.

During reading of data, the data register 24B temporarily stores the data detected by the sense amplifier unit group 24A, and serially transfers the data to the input and output circuit 22. In addition, during writing of data, the data register 24B temporarily stores the data serially transferred from the input and output circuit 22, and transfers the data to the sense amplifier unit group 24A. The data register 24B includes an SRAM.

### 1-3. Block Configuration of Memory Cell Array

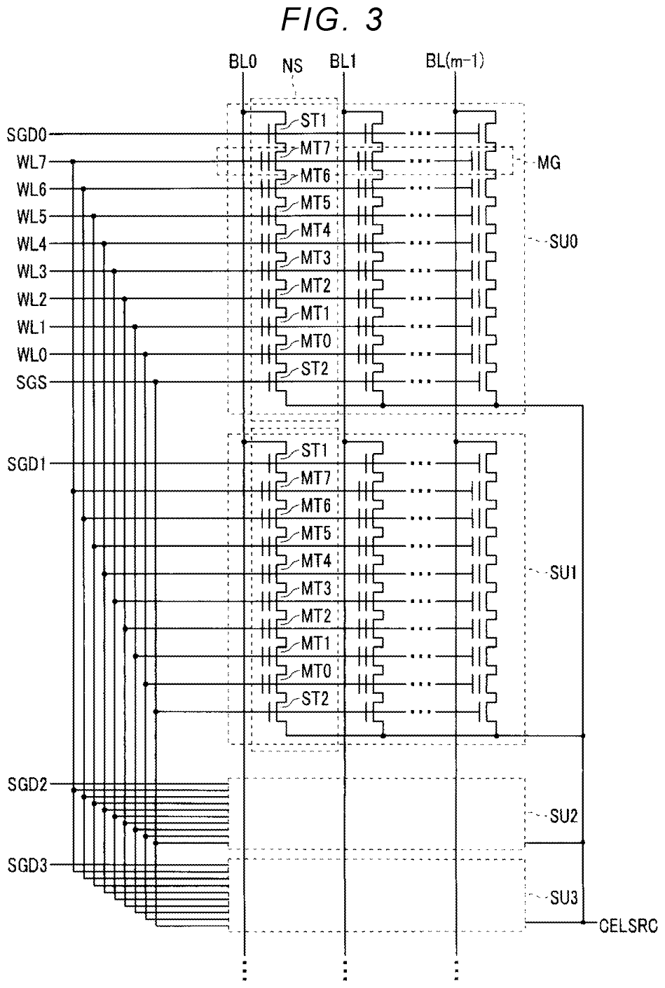

FIG. 3 is a diagram showing a configuration example of a block of a memory cell array having a three-dimensional structure. FIG. 3 shows one block BLK among a plurality of blocks constituting the memory cell array 23. The other blocks of the memory cell array 23 also have the same configuration as that in FIG. 3.

As shown, the block BLK includes, for example, four string units (SU0 to SU3). Each of the string units SU includes a plurality of NAND strings NS. Here, each of the NAND strings NS includes eight memory cell transistors MT (MT0 to MT7) and select gate transistors ST1 and ST2. Each of the memory cell transistors MT includes a gate and a charge storage layer, and stores data in a nonvolatile manner. The number of the memory cell transistors MT provided in the NAND string NS is eight for convenience, and may be more than eight.

The select gate transistors ST1 and ST2 are shown as one transistor in an electric circuit, and may have the same structure as the memory cell transistors MT. For example, a plurality of select gate transistors may be used as the select gate transistors ST1 and ST. Further, dummy cell transistors may be provided between the memory cell transistor MT and the select gate transistor ST1 as well as between the memory cell transistor MT and the select gate transistor ST2.

The memory cell transistors MT are connected in series between the select gate transistors ST1 and ST2. The memory cell transistor MT7 on one end side is connected to the select gate transistor ST1, and the memory cell transistor MT0 on the other end side is connected to the select gate transistor ST2.

Gates of the select gate transistors ST1 of the string units SU0 to SU3 are connected to select gate lines SGD0 to SGD3 (hereinafter, referred to as a select gate line SGD when it is not necessary to distinguish them from one another), respectively. On the other hand, gates of the select gate transistors ST2 are commonly connected to one select gate line SGS among the plurality of string units SU in the same block BLK. Gates of the memory cell transistors MT0 to MT7 in the same block BLK are commonly connected to word lines WL0 to WL7, respectively. That is, the word lines WL0 to WL7 and the select gate line SGS are commonly connected among the plurality of string units SU0 to SU4 in the same block BLK, whereas the select gate line SGD is independent for each of the string units SU0 to SU3 even in the same block BLK.

The word lines WL0 to WL7 are connected to the gates of the memory cell transistors MT0 to MT7 constituting the NAND string NS, respectively. In the block BLK, gates of memory cell transistors MTi in the same row are connected to the same word line WLi. In the following description, the NAND string NS may be simply referred to as a “string”.

Each NAND string NS is connected to a corresponding bit line. Therefore, each memory cell transistor MT is connected to a bit line via the select gate transistor ST or another memory cell transistor MT that are provided in the NAND string NS. As described above, the data of the memory cell transistors MT in the same block BLK is collectively erased. On the other hand, reading and writing of data are executed in units of memory cell groups MG (or in units of pages). In the present description, a plurality of memory cell transistors MT that are connected to one word line WLi and that belong to one string unit SU are defined as a memory cell group MG. During the read operation and the write operation, in accordance with the physical address, one word line WLi and one select gate line SGD are selected, and the memory cell group MG is selected.

### 1-4. Cross-Sectional Structure of Nonvolatile Memory

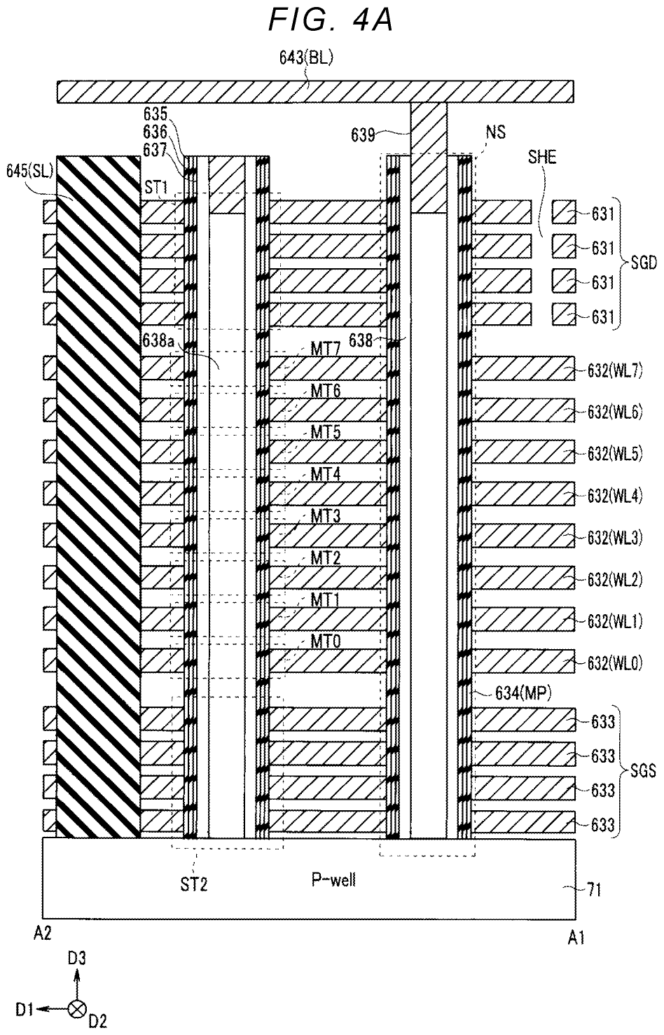

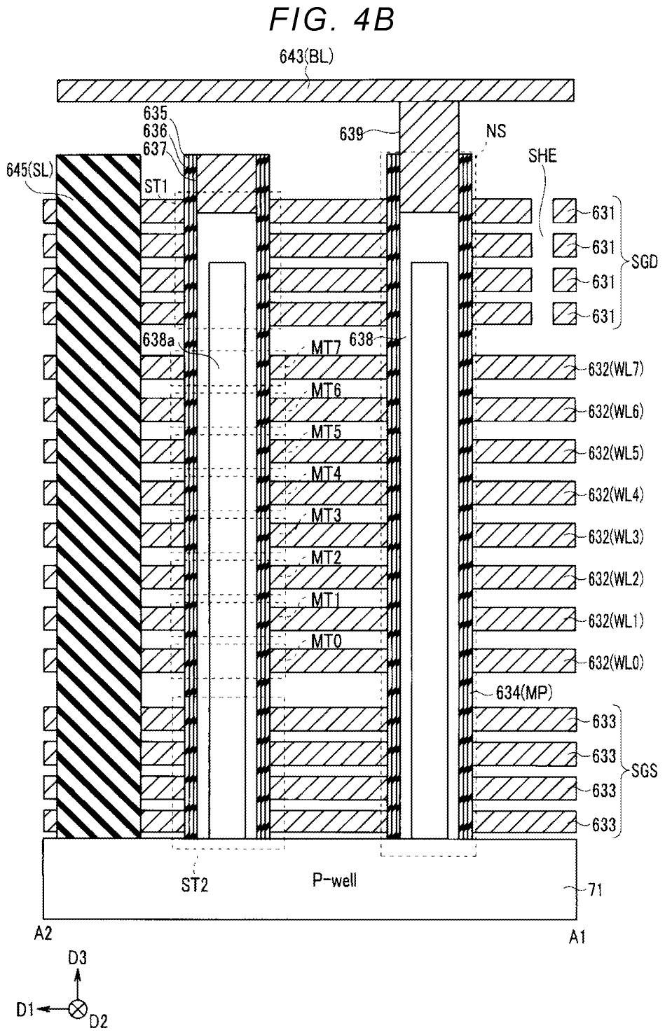

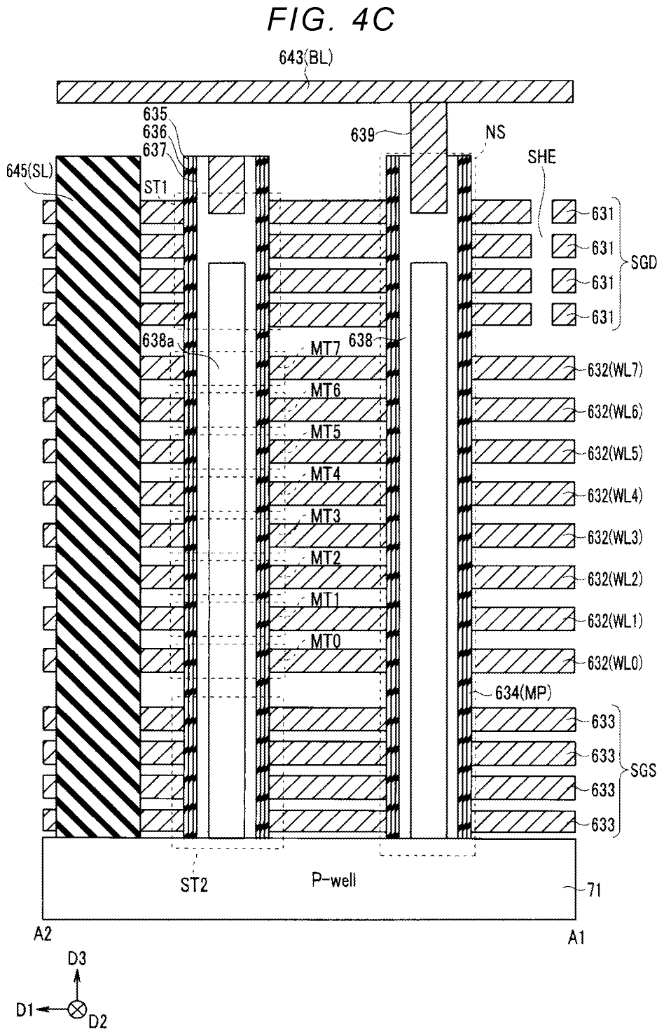

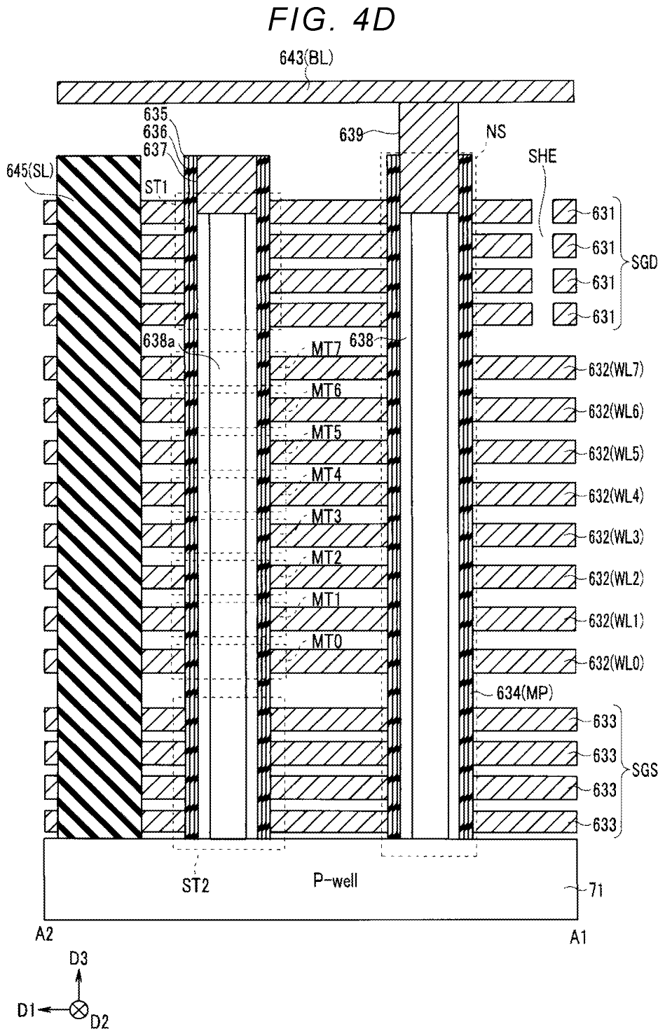

Next, a cross-sectional structure of a memory cell array will be described with reference to FIG. 4A. FIG. 4A is a cross-sectional view of a part of a region of the memory cell array having a three-dimensional structure.

The memory cell array 23 has a three-dimensional structure. As shown in FIG. 4A, a plurality of NAND strings NS are formed on a p-type well region (P-well). That is, a plurality of wiring layers 633 functioning as the select gate line SGS are stacked on the p-type well region. Further, a plurality of wiring layers 632 that are first wirings functioning as the word line WLi are stacked above the wiring layers 633. Further, a plurality of wiring layers 631 that are second wirings functioning as the select gate line SGD are stacked above the wiring layers 632. Among the wiring layers 631, 632, and 633, insulating layers (not shown) are provided between adjacent wiring layers in a D3 direction. In addition, an insulating layer SHE that separates the plurality of string units SU included in one block BLK extends in a D2 direction. The insulating layer SHE extends, in the direction D3, to the plurality of wiring layers 631 constituting the select gate line SGD, and separates the string units SU from one another. With such a configuration, in the structure shown in FIG. 4A, a width of the wiring layer 631 in a direction D1 is smaller than a width of the wiring layer 632 in the direction D1. FIG. 4A shows a structure in which eight wiring layers 632 functioning as the word line WLi are stacked for convenience, and more wiring layers 632 may be stacked.

A memory pillar 634 penetrates the wiring layers 631, 632, and 633, and reaches the p-type well region. A block insulating film 635, a charge storage layer 636, and a tunnel insulating film 637 are sequentially formed on a side surface of the memory pillar 634, and a semiconductor pillar 638 is embedded in the memory pillar 634. The semiconductor pillar 638 contains, for example, polysilicon, and functions as a region in which a channel is formed during the operation of the memory cell transistor MT and the select gate transistors ST1 and ST2 that are provided in the NAND string NS. For example, portions where the memory pillar 634 and the wiring layers 631 intersect function as the select gate transistors ST1. Portions where the memory pillar 634 and the wiring layers 633 intersect function as the select gate transistors ST2. Portions where the memory pillar 634 and the wiring layers 632 intersect function as the memory cell transistors (memory cells) MT.

Further, a core layer (a core insulating layer) 638a is embedded in the semiconductor pillar 638. An upper surface of the core layer 638a is formed at a position lower than an upper surface of the uppermost wiring layer 631 (a second wiring layer) by a predetermined distance in the D3 direction. In addition, the upper surface of the core layer 638a is in contact with a lower surface of the contact plug 639. That is, the lower surface of the contact plug 639 is formed at a position lower than the upper surface of the uppermost wiring layer 631 by a predetermined distance in the direction D3 so as to be in contact with the upper surface of the core layer 638a. The lower surface of the contact plug 639 may be in contact with the semiconductor pillar 638 above a lower surface of the lowermost wiring layer 631 among the plurality of wiring layers 631. The core layer 638a constitutes an insulating layer, and the semiconductor pillar 638 constitutes a semiconductor layer.

The block insulating film 635, the tunnel insulating film 637, the gate insulating film 641, the core layer 638a, and the insulating layer 642 are formed of, for example, a silicon oxide film. The charge storage layer 636 is formed of, for example, a silicon nitride film.

Wiring layers 643 are provided above an upper surface of the memory pillar 634 via an insulating layer. The wiring layers 643 serving as third wirings and extending in the direction D1 are formed in a band shape and correspond to bit lines BL. The plurality of wiring layers 643 are arranged at intervals in the direction D2.

The lower surface of the contact plug 639 is in contact with the upper surface of the core layer 638a in the memory pillar 634, and the side surface of the contact plug 639 is in contact with the semiconductor pillar 638. The semiconductor pillar 638 in a region in contact with the contact plug 639 does not substantially contain an impurity that is a dopant (for example, phosphorus (P), arsenic (As), or boron (B)). That is, in the semiconductor pillar 638, dopant impurity concentrations in the region in contact with the contact plug 639 and in a region facing the wiring layers 631 are equal to or less than a detection limit. As a method for measuring the dopant impurity concentration, for example, energy dispersive X-ray spectroscopy (TEM-EDX) is used. The contact plug 639 is formed of, for example, a metal such as tungsten, and electrically connects the semiconductor pillar 638 and the wiring layers 643. Specifically, the wiring layers 643 are electrically connected, via the contact plug 639, to the semiconductor pillar 638 of one memory pillar 634 corresponding to the respective string unit SU.

With the above configuration, in a region where the wiring layers 631 functioning as the select gate line SGD are stacked, the contact plug 639 made of a metal material is connected to the semiconductor pillar 638 in which the channel is formed, and holes are supplied. The holes are generated at an interface between the contact plug 639 and the semiconductor pillar 638.

The holes are generated at an interface between the contact plug 639 and the semiconductor pillar 638 in which a channel is formed. Therefore, as shown in FIG. 4B, the semiconductor pillar 638 may be provided on the core layer 638a, and the lower surface of the contact plug 639 and the upper surface of the semiconductor pillar 638 may be in direct contact with each other. FIG. 4B is another cross-sectional view of a part of a region of a memory cell array having a three-dimensional structure.

As shown in FIG. 4B, the semiconductor pillar 638 made of, for example, polysilicon is formed on the upper surface of the core layer 638a. The contact plug 639 is formed on the upper surface of the semiconductor pillar 638. With such a configuration, holes are generated at the interface between the contact plug 639 and the semiconductor pillar 638 in which a channel is formed.

Structures of the semiconductor pillar 638, the core layer 638a, and the contact plug 639 are not limited to the structures shown in FIGS. 4A and 4B. FIG. 4C and 4D are other cross-sectional views of a part of a region of a memory cell array having a three-dimensional structure.

As shown in FIG. 4C, the semiconductor pillar 638 made of, for example, polysilicon is formed on the upper surface of the core layer 638a. The contact plug 639 having a width smaller than the width of the semiconductor pillar 638 is formed in a memory pillar MP. That is, the lower surface and the side surface of the contact plug 639 are in contact with the upper surface and the side surface of the semiconductor pillar 638. With such a configuration, holes are generated at the interface between the contact plug 639 and the semiconductor pillar 638 in which a channel is formed.

As shown in FIG. 4D, the contact plug 639 having a width larger than the width of the core layer 638a is formed in the memory pillar MP. That is, the lower surface of the contact plug 639 is in contact with the upper surfaces of the semiconductor pillar 638 and the core layer 638a. With such a configuration, holes are generated at the interface between the contact plug 639 and the semiconductor pillar 638 in which a channel is formed.

### 2. Manufacturing Method

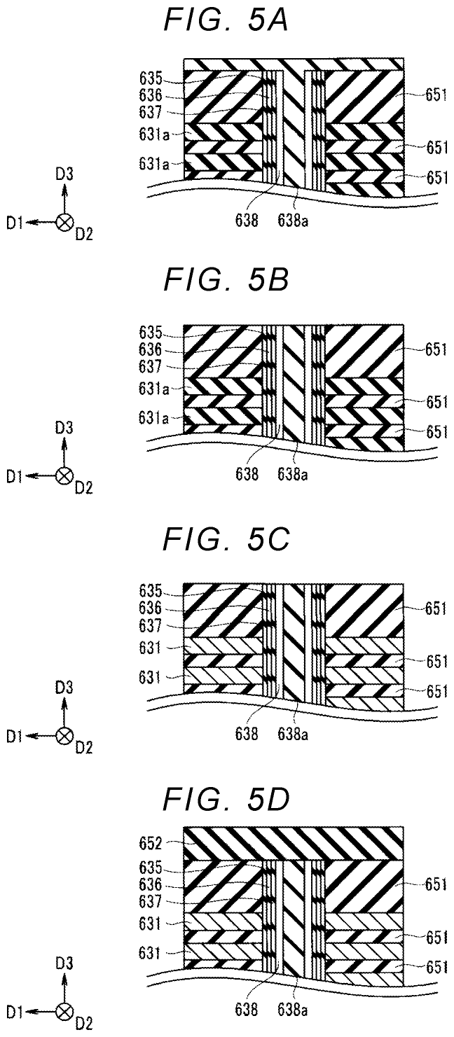

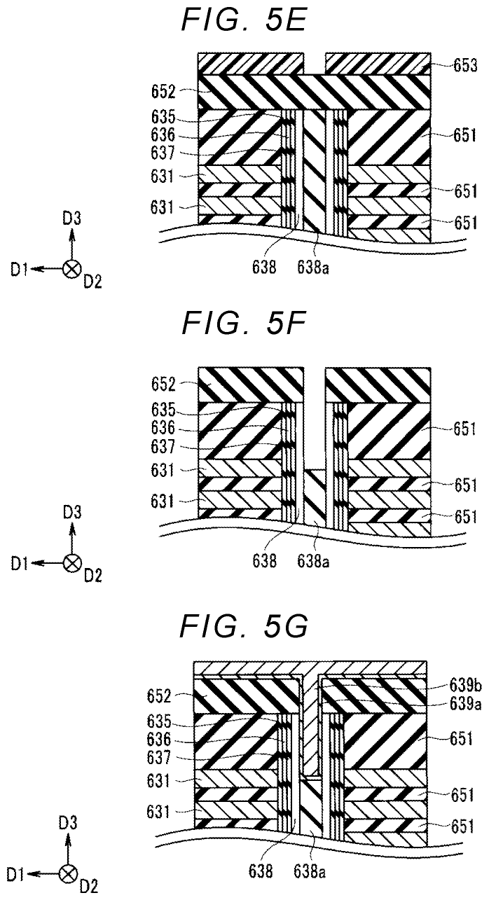

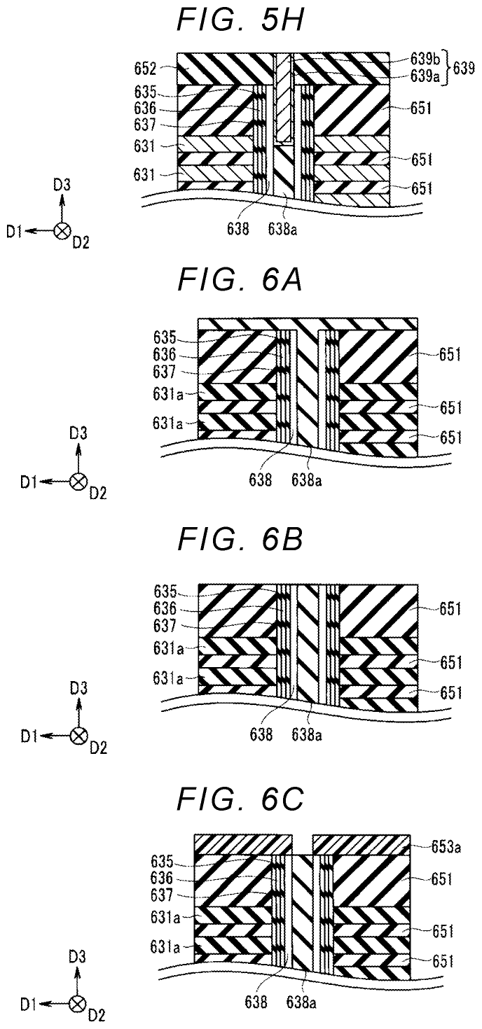

Next, an example of a method for manufacturing the memory cell array 23 according to the present embodiment will be described. FIGS. 5A to 5H are cross-sectional views of a memory cell array showing an example of a manufacturing process of the memory cell array shown in FIG. 4A. The cross-sectional views in FIGS. 5A to 5H show below the contact plug 639 and above a second layer from the top of the wiring layers 631.

Hereinafter, as a method for forming the wiring layers 631, 632, and 633, a method (hereinafter, referred to as “replacement”) of forming, as a sacrificial layer, a structure corresponding to the wiring layers 631, 632, and 633 and then removing the sacrificial layer to replace the sacrificial layer with a conductive material will be described.

First, insulating layers and four sacrificial layers corresponding to the wiring layers 633 are alternately stacked on a semiconductor substrate 71 by chemical vapor deposition (CVD) or the like. Next, insulating layers and eight sacrificial layers corresponding to the wiring layers 632 are alternately stacked. Next, insulating layers 651 and four sacrificial layers 631a corresponding to the wiring layers 631 are alternately stacked. A material having a high selectivity to wet etching corresponding to the insulating layers 651 is used for the sacrificial layer 631a. For example, when the insulating layer 651 is formed of a silicon oxide film, a silicon nitride film is used for the sacrificial layer 631a.

Next, the memory pillar MP is formed. Specifically, first, a hard mask is formed on an upper surface of the uppermost insulating layer 651, and the hard mask in a formation region of the memory pillar MP is removed. That is, the hard mask is patterned such that the insulating layer 651 is exposed only in the formation region of the memory pillar MP. Next, anisotropic etching is used to form a deep hole (a hole) penetrating the 16 sacrificial layers 631a and the insulating layers, and a bottom surface of the deep hole reaches the semiconductor substrate 71 serving as the source line. After removing the hard mask, the block insulating film 635, the charge storage layer 636, and the tunnel insulating film 637 are sequentially stacked.

Subsequently, the uppermost insulating layer 651, the block insulating film 635 on the bottom surface of the hole, the charge storage film 636, and the tunnel insulating film 637 are removed using anisotropic etching or the like, and the semiconductor substrate 71 is exposed at the bottom surface of the hole. A polysilicon film and a silicon oxide film are sequentially deposited on an entire surface by CVD or the like, and the semiconductor pillar 638 and the core layer 638a are embedded in the hole, thereby forming a structure shown in FIG. 5A.

Subsequently, etch back (etching an entire surface of a portion exposed on an upper surface by anisotropic etching without using the hard mask) is executed to remove the silicon oxide film on the upper surfaces of the uppermost insulating layer 651 and the memory pillar MP, thereby forming a structure shown in FIG. 5B.

Subsequently, the replacement is executed. Specifically, a slit SL whose bottom surface reaches the semiconductor substrate 71 is processed into a predetermined place by anisotropic etching. Next, the sacrificial layer 632a is removed from the slit SL by wet etching to form a gap. After embedding the gap with a conductive film (for example, tungsten), the conductive film formed in the slit SL and on the uppermost insulating layer 651 is removed to form the wiring layers 631, 632, and 633. Then, an insulating layer 645 is embedded in the slit SL. Accordingly, the replacement is completed, the formation of the wiring layers 631 serving as the select gate line SGD, the wiring layers 632 serving as the word line WL, and the wiring layers 633 serving as the select gate line SGS is completed, and a structure shown in FIG. 5C is formed.

As described above, the block BLK includes, for example, four string units (SU0 to SU3). The string units SU0 to SU3 are separated by the insulating layer SHE. The insulating layer SHE extends to the four wiring layers 631 constituting the select gate line SGD to separate the string units SU0 to SU3 from one another. The insulating layer SHE is generated by cutting the wiring layers 631 after the replacement.

Subsequently, the contact plug 639 is formed. First, an insulating layer 652 is deposited on the entire upper surface by CVD or the like to form a structure shown in FIG. 5D. The insulating layer 652 is formed of, for example, a silicon oxide film having a thickness of 120 nm.

Subsequently, a hard mask 653 is formed on an upper surface of the insulating layer 652. Then, the hard mask 653 in a formation region of the contact plug 639 is removed. That is, the hard mask 653 is patterned such that the insulating layer 652 is exposed only in the formation region of the contact plug 639, thereby forming a structure in FIG. 5E.

Subsequently, the core layer 638a and the insulating layer 652 in a region where the hard mask 653 is not formed are etched by anisotropic etching to a position lower than the upper surface of the uppermost wiring layer 631 by a predetermined distance, thereby forming a contact hole. By removing the hard mask 653 by asking, wet etching, or the like, a structure shown in FIG. 5F is formed.

Subsequently, a conductive film 639a (for example, titanium/titanium nitride) and a conductive film 639b (for example, tungsten) are embedded in the contact hole by CVD or the like, thereby forming a structure shown in FIG. 5G.

Finally, the conductive films 639a and 639b formed on the uppermost insulating layer 652 are removed by chemical mechanical polishing (CMP), thereby forming the contact plug 639. By executing the above procedures, a structure shown in FIG. 5H is formed.

Subsequently, the wiring layers 643 are formed on the upper layer of the contact plug 639 to form the structure shown in FIG. 4A.

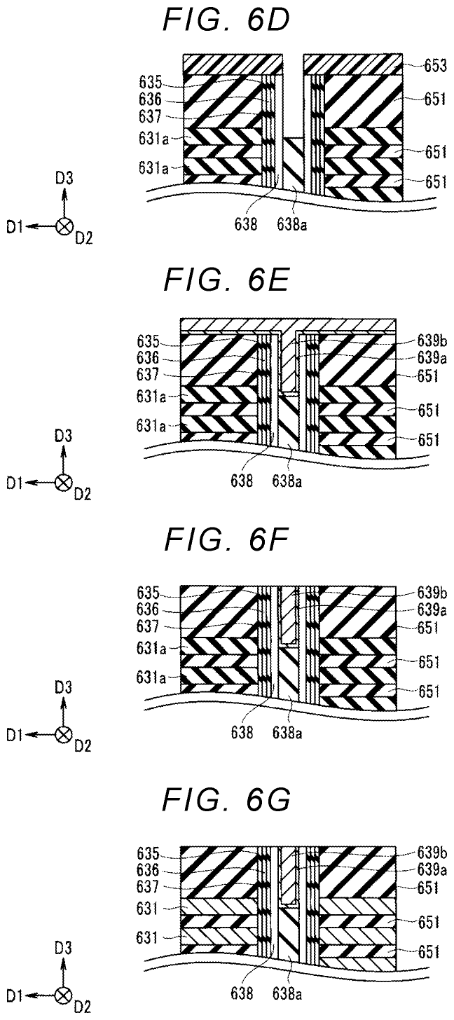

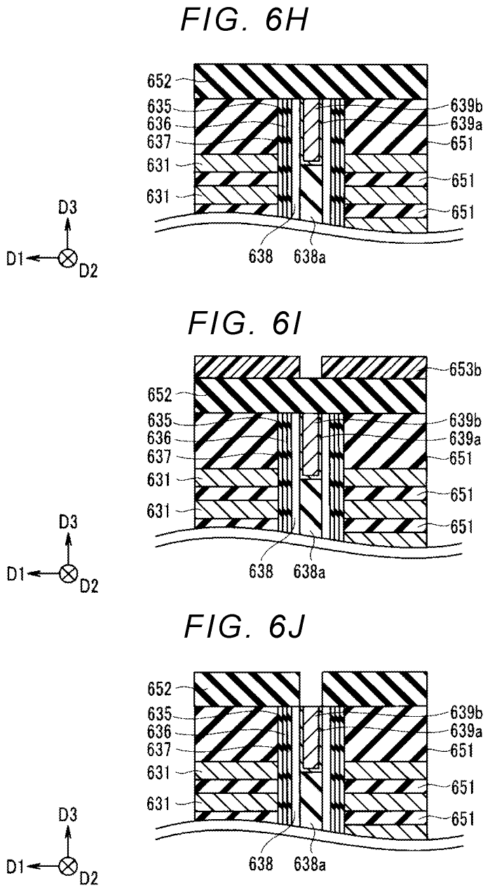

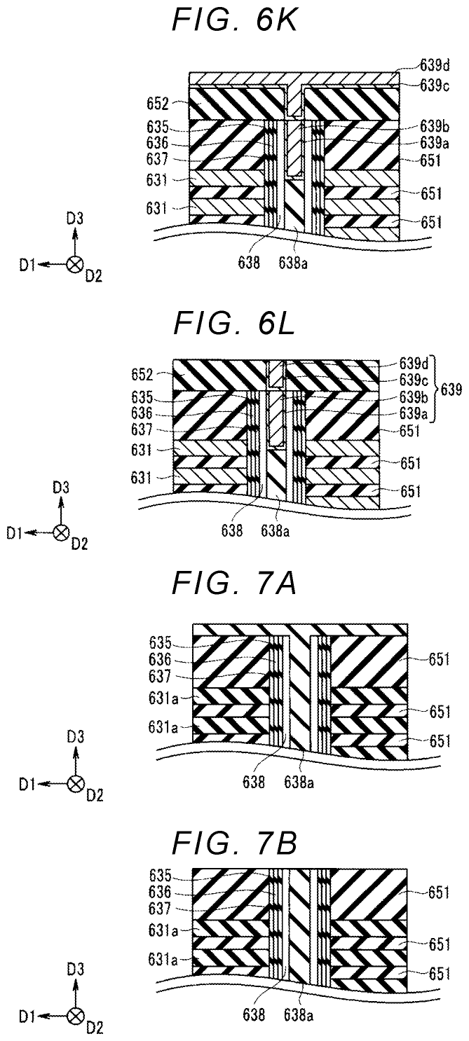

Next, another example of a method for manufacturing the memory cell array 23 shown in FIG. 4A will be described. FIGS. 6A to 6L are cross-sectional views of a memory cell array showing another example of the manufacturing process of the memory cell array shown in FIG. 4A.

First, the semiconductor pillar 638 and the core layer 638a are embedded in the hole by the same manufacturing method as that in FIG. 5A described above, thereby forming a structure shown in FIG. 6A.

Subsequently, etch back is executed to remove the silicon oxide film on the upper surfaces of the uppermost insulating layer 651 and the memory pillar MP, thereby forming a structure shown in FIG. 6B.

Subsequently, a hard mask 653a is formed on the upper surfaces of the memory pillar MP and the insulating layer 651. Then, the hard mask 653a in the formation region of the contact plug 639 is removed. That is, the hard mask 653a is patterned such that the core layer 638a is exposed only in the formation region of the contact plug 639, thereby forming a structure in FIG. 6C.

Subsequently, the core layer 638a in which the hard mask 653a is not formed is etched by anisotropic etching to a position lower than an upper surface of the uppermost sacrificial layer 631a by a predetermined distance to form a contact hole, thereby forming the structure in FIG. 6D.

Subsequently, the hard mask 653a is removed by asking, wet etching, or the like, and the conductive film 639a (for example, titanium/titanium nitride) and the conductive film 639b (for example, tungsten) are embedded in the contact hole, thereby forming a structure shown in FIG. 6E.

Subsequently, the conductive films 639a and 693b formed on the memory pillar MP and the uppermost insulating layer 651 are removed by CMP, thereby forming a structure shown in FIG. 6F. Subsequently, the wiring layers 631, 632, and 633 are formed by the replacement, and a structure shown in FIG. 6G is formed.

Subsequently, the insulating layer 652 is deposited on the entire upper surface by CVD or the like, thereby forming a structure shown in FIG. 6H. Subsequently, a hard mask 653b is formed on the upper surface of the insulating layer 652. Then, the hard mask 653b in the formation region of the contact plug 639 is removed. That is, the hard mask 653b is patterned such that the insulating layer 652 is exposed only in the formation region of the contact plug 639, thereby forming a structure shown in FIG. 6I.

Subsequently, the insulating layer 652 in a region where the hard mask 653b is not formed is etched by anisotropic etching to the upper surfaces of the conductive films 639a and 639b, thereby forming a contact hole. By removing the hard mask 653b by asking, wet etching, or the like, a structure shown in FIG. 6J is formed.

Subsequently, a conductive film 639c (for example, titanium/titanium nitride) and a conductive film 639d (for example, tungsten) are embedded in the contact hole by CVD or the like, thereby forming a structure shown in FIG. 6K.

Finally, the conductive films 639c and 639d formed on the uppermost insulating layer 652 are removed by CMP to form the contact plug 639. By executing the above procedures, a structure shown in FIG. 6L is formed.

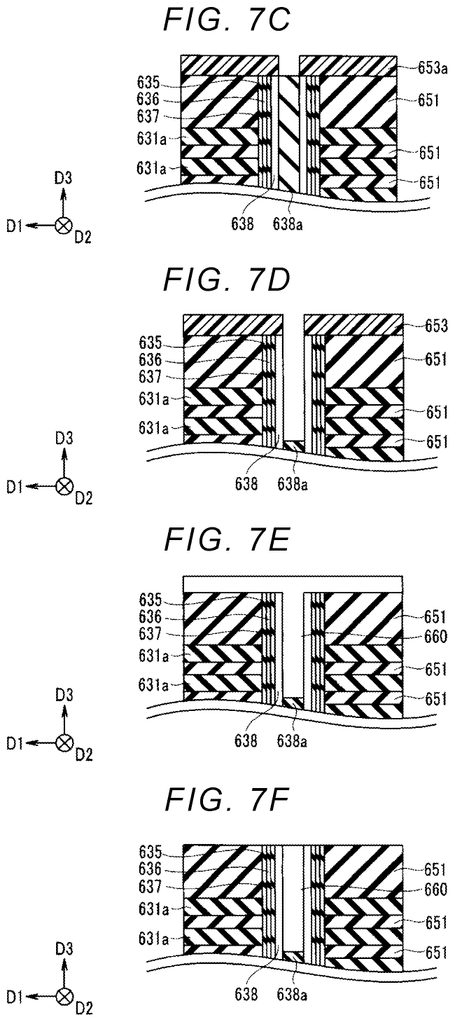

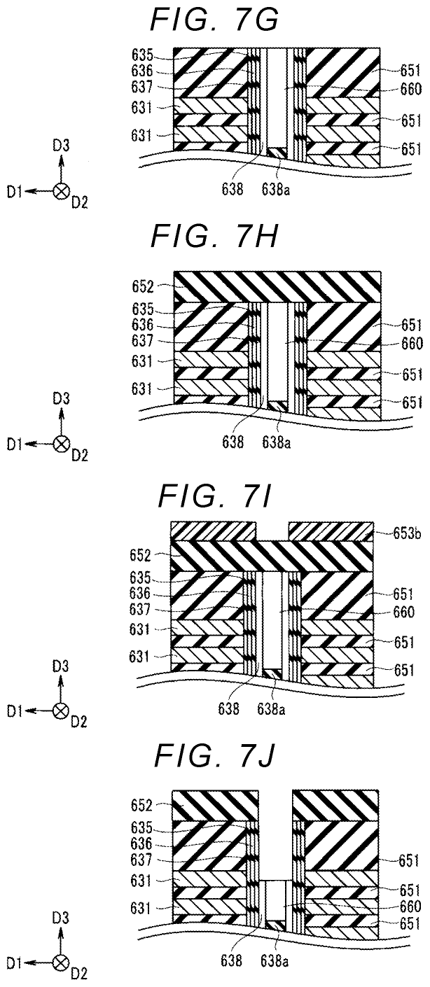

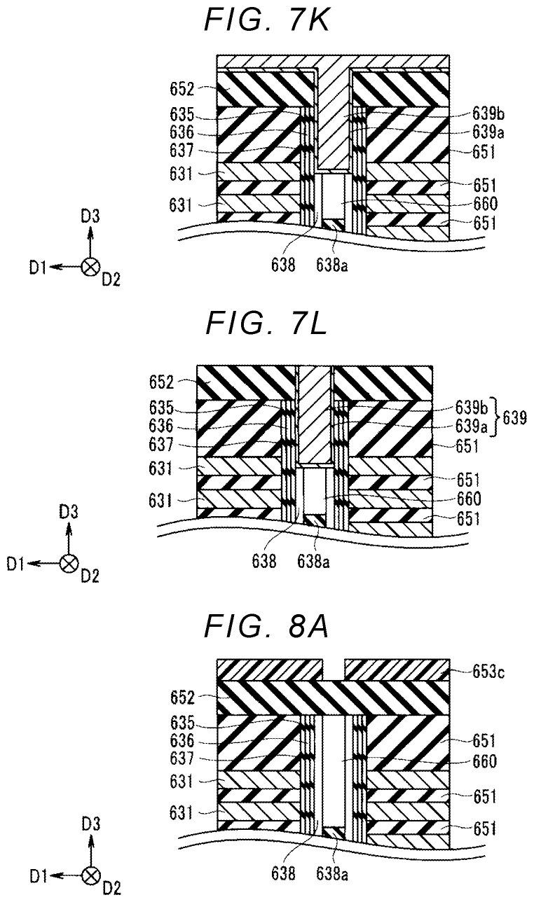

Next, an example of a method for manufacturing the memory cell array 23 shown in FIG. 4B will be described. FIGS. 7A to 7L are cross-sectional views of a memory cell array showing an example of a manufacturing process of the memory cell array shown in FIG. 4B.

First, the semiconductor pillar 638 and the core layer 638a are embedded in the hole by the same manufacturing method as that in FIG. 5A described above, thereby forming a structure shown in FIG. 7A.

Subsequently, etch back is executed to remove the silicon oxide film on the upper surfaces of the uppermost insulating layer 651 and the memory pillar MP, thereby forming a structure shown in FIG. 7B.

Subsequently, the hard mask 653a is formed on the upper surfaces of the memory pillar MP and the insulating layer 651. Then, the hard mask 653a in the formation region of the contact plug 639 is removed. That is, the hard mask 653a is patterned such that the core layer 638a is exposed only in the formation region of the contact plug 639, thereby forming a structure in FIG. 7C.

Subsequently, the core layer 638a in which the hard mask 653a is not formed is etched by anisotropic etching to a position lower than a lower surface of the second sacrificial layer 631a from the top by a predetermined distance to form a hole, thereby forming a structure in FIG. 7D.

Subsequently, a polysilicon film 660 is deposited on the entire surface by CVD or the like, and the polysilicon film 660 is embedded in the hole, thereby forming a structure in FIG. 7E.

Subsequently, etch back is executed to remove the polysilicon film 660 on the upper surfaces of the uppermost insulating layer 651 and the memory pillar MP, thereby forming a structure shown in FIG. 7F.

Subsequently, the replacement is executed to form the wiring layers 631, 632, and 633, thereby forming a structure shown in FIG. 7G.

Subsequently, the contact plug 639 is formed. First, the insulating layer 652 is deposited on the entire upper surface by CVD or the like, thereby forming a structure shown in FIG. 7H.

Subsequently, the hard mask 653b is formed on the upper surface of the insulating layer 652. Then, the hard mask 653b in the formation region of the contact plug 639 is removed. That is, the hard mask 653b is patterned such that the insulating layer 652 is exposed only in the formation region of the contact plug 639, thereby forming a structure shown in FIG. 7I.

Subsequently, the insulating layer 652 in a region where the hard mask 653b is not formed, the semiconductor pillar 638, and the polysilicon film 660 are etched by anisotropic etching to a position lower than the upper surface of the uppermost wiring layer 631 by a predetermined distance, thereby forming a contact hole. The hard mask 653b is removed by asking, wet etching, or the like, thereby forming a structure shown in FIG. 7J.

Subsequently, the conductive film 639a (for example, titanium/titanium nitride) and the conductive film 639b (for example, tungsten) are embedded in the contact hole by CVD or the like, thereby forming a structure shown in FIG. 7K.

Finally, the conductive films 639a and 639b formed on the uppermost insulating layer 652 are removed by CMP to form the contact plug 639. By executing the above procedures, a structure shown in FIG. 7L is formed.

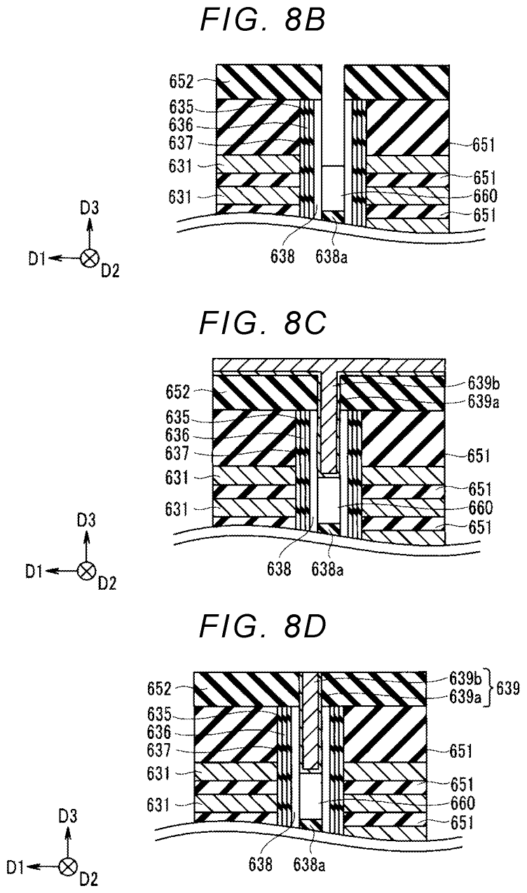

Next, an example of a method for manufacturing the memory cell array 23 shown in FIG. 4C will be described. FIGS. 8A to 8D are cross-sectional views of a memory cell array showing an example of a manufacturing process of the memory cell array shown in FIG. 4C.

The manufacturing process of the memory cell array shown in FIG. 4C is the same as the manufacturing process of the memory cell array shown in FIG. 4B up to the middle of the manufacturing process (FIGS. 7A to 7H). First, the insulating layer 652 is deposited on the entire upper surface by the manufacturing method in FIGS. 7A to 7H.

Subsequently, a hard mask 653c is formed on the upper surface of the insulating layer 652. Then, the hard mask 653c in the formation region of the contact plug 639 is removed. That is, the hard mask 653c is patterned such that the insulating layer 652 is exposed only in the formation region of the contact plug 639, thereby forming a structure shown in FIG. 8A. A region where the hard mask 653c is not formed is smaller than the region shown in FIG. 7I where the hard mask 653b is not formed.

Subsequently, the polysilicon film 660 and the insulating layer 652 in the region where the hard mask 653c is not formed are etched, by anisotropic etching, to a position lower than the upper surface of the uppermost wiring layer 631 by a predetermined distance, thereby forming a contact hole. The hard mask 653c is removed by asking, wet etching, or the like, thereby forming a structure shown in FIG. 8B.

Subsequently, the conductive film 639a (for example, titanium/titanium nitride) and the conductive film 639b (for example, tungsten) are embedded in the contact hole by CVD or the like, thereby forming a structure shown in FIG. 8C.

Finally, the conductive films 639a and 639b formed on the uppermost insulating layer 652 are removed by CMP to form the contact plug 639. By executing the above procedures, a structure shown in FIG. 8D is formed.

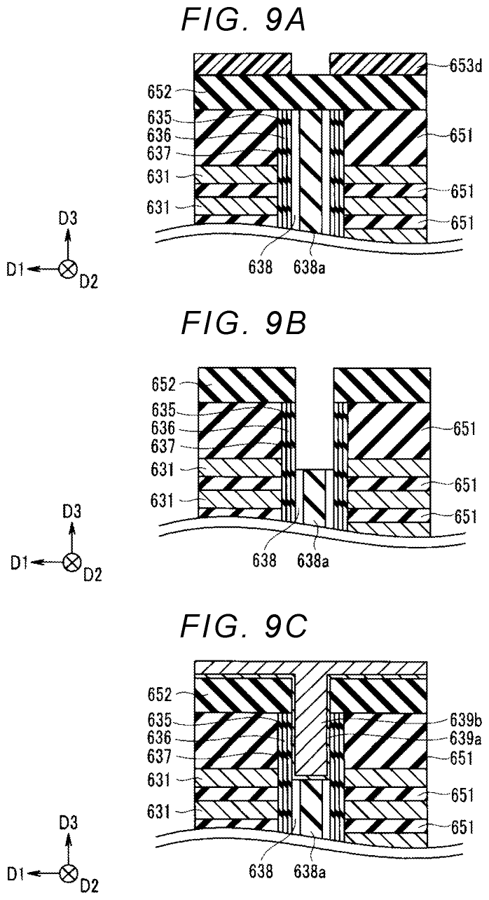

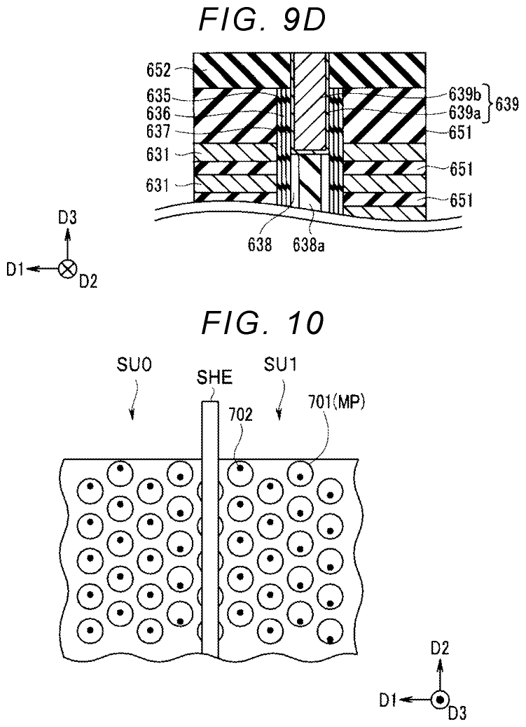

Next, an example of a method for manufacturing the memory cell array 23 shown in FIG. 4D will be described. FIGS. 9A to 9D are cross-sectional views of a memory cell array showing an example of a manufacturing process of the memory cell array shown in FIG. 4D.

The manufacturing process of the memory cell array shown in FIG. 4D are the same as the manufacturing process of the memory cell array shown in FIG. 4A up to the middle of the manufacturing process (FIGS. 5A to 5D). First, the insulating layer 652 is deposited on the entire upper surface by the manufacturing method in FIGS. 5A to 5D.

Subsequently, a hard mask 653d is formed on the upper surface of the insulating layer 652. Then, the hard mask 653d in the formation region of the contact plug 639 is removed. That is, the hard mask 653d is patterned such that the insulating layer 652 is exposed only in the formation region of the contact plug 639, thereby forming a structure shown in FIG. 9A. A region where the hard mask 653d is not formed is larger than the region shown in FIG. 5E where the hard mask 653 is not formed.

Subsequently, the insulating layer 652 in the region where the hard mask 653d is not formed, the semiconductor pillar 638, and the core layer 638a are etched by anisotropic etching to a position lower than the upper surface of the uppermost wiring layer 631 by a predetermined distance, thereby forming a contact hole. The hard mask 653d is removed by asking, wet etching, or the like, thereby forming a structure shown in FIG. 9B.

Subsequently, the conductive film 639a (for example, titanium/titanium nitride) and the conductive film 639b (for example, tungsten) are embedded in the contact hole by CVD or the like, thereby forming a structure shown in FIG. 9C.

Finally, the conductive films 639a and 639b formed on the uppermost insulating layer 652 are removed by CMP to form the contact plug 639. By executing the above procedures, a structure shown in FIG. 9D is formed.

Here, a highly integrated structure to which the above manufacturing process is applied will be described.

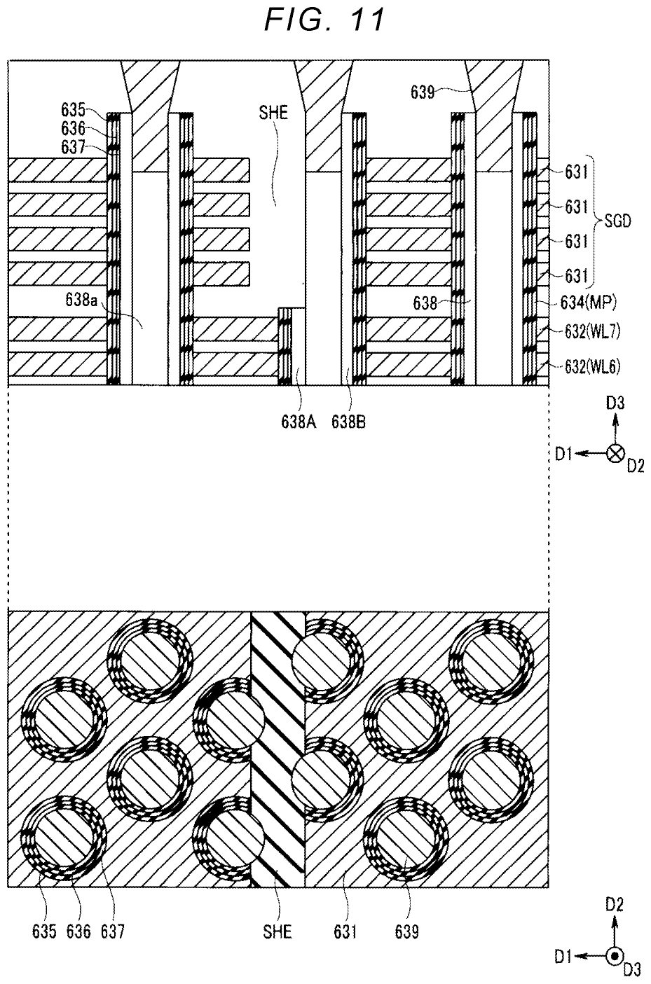

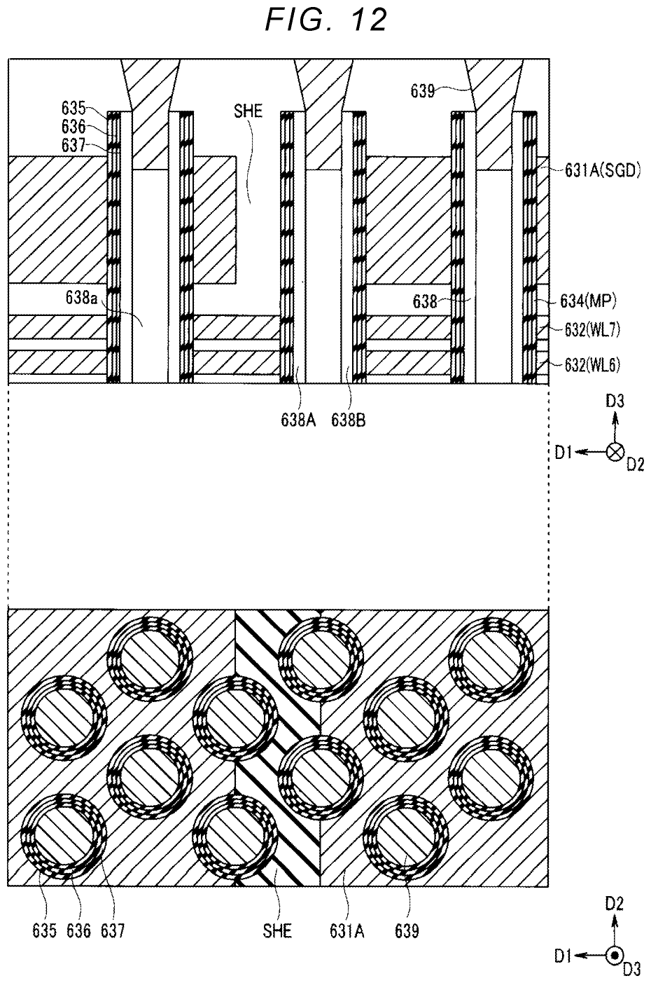

FIG. 10 is a top view showing an example of a processed shape of the insulating layer SHE in the memory cell arrays shown in FIGS. 4A to 4D. FIG. 10 shows a part of a region of the string units SU0 and SU1. FIG. 11 is a top view and a cross-sectional view showing an example of a highly integrated structure to which the manufacturing process of the embodiment is applied. FIG. 12 is a top view and a cross-sectional view showing another example of the highly integrated structure to which the manufacturing process of the embodiment is applied.

As shown in FIG. 10, a plurality of memory pillars MP are disposed in the string units SU0 and SU1. The memory pillars MP are connected to the bit lines BL by contact plugs 702, respectively. The string units SU0 and SU1 are separated by the insulating layer SHE formed on the memory pillar MP.

In a structure shown in FIG. 11, after the wiring layers 631 are formed by the replacement, the wiring layers 631 on which the insulating layer SHE is formed and a side surface of the memory pillar MP adjacent to a region in which the insulating layer SHE is formed are removed. Thereafter, the contact plug 639 is generated by a photo engraving process (PEP) or the like. In the structure shown in FIG. 11, the width of the wiring layer 631 in the direction D1 is smaller than the width of the wiring layer 632 in the direction D1.

The semiconductor pillar 638 includes a first semiconductor region 638A and a second semiconductor region 638B that are arranged in a second direction (D1 direction) intersecting a first direction (D3 direction). An upper surface of the first semiconductor region 638A is lower than an upper surface of the second semiconductor region 638B.

In a structure shown in FIG. 12, the insulating layer SHE is processed after a wiring layer 631A functioning as the select gate line SGD is generated by the polysilicon film. Then, after the insulating layer SHE is processed, the memory pillar MP is generated. Therefore, the memory pillar MP adjacent to the insulating layer SHE remains. In the structure shown in FIG. 12, the width of the wiring layer 631A in the direction D1 is smaller than the width of the wiring layer 632 in the direction D1.

The semiconductor pillar 638 includes the first semiconductor region 638A and the second semiconductor region 638B that are arranged in the second direction (D1 direction) intersecting the first direction (D3 direction). The first semiconductor region 638A does not face the wiring layer 631A, and the second semiconductor region 638B faces the wiring layer 631A.

In the structure shown in FIG. 10, the memory pillar MP whose upper portion is cut by the insulating layer SHE cannot be connected to the bit line BL.

On the other hand, in the structures shown in FIGS. 11 and 12, the memory pillar MP adjacent to the insulating layer SHE can be connected to the bit line BL, and high integration can be achieved.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a first wiring;
a second wiring provided above the first wiring in a first direction;
a memory pillar penetrating at least one of a portion of the first wiring or a portion of the second wiring in the first direction;
a semiconductor layer provided in the memory pillar and extending in the first direction; and
a contact plug containing a metal and having a lower surface provided in the memory pillar, the lower surface being in contact with the semiconductor layer below an upper surface of the second wiring.

2. The semiconductor memory device according to claim 1, further comprising:
a core insulating layer provided along an inner side surface of the semiconductor layer, wherein
the lower surface of the contact plug is in contact with an upper surface of the core insulating layer.

3. The semiconductor memory device according to claim 1, further comprising:
a core insulating layer provided along an inner side surface of the semiconductor layer, wherein
the semiconductor layer includes a first semiconductor layer provided on an upper surface of the core insulating layer, and a second semiconductor layer that covers side surfaces of the core insulating layer and the first semiconductor layer, and
the lower surface of the contact plug is in contact with upper surfaces of the first semiconductor layer and the second semiconductor layer.

4. The semiconductor memory device according to claim 1, further comprising:
a core insulating layer provided along an inner side surface of the semiconductor layer, wherein
the semiconductor layer includes a first semiconductor layer provided on an upper surface of the core insulating layer, and a second semiconductor layer that covers side surfaces of the core insulating layer, the first semiconductor layer, and the contact plug, and
the lower surface of the contact plug is in contact with an upper surface of the first semiconductor layer.

5. The semiconductor memory device according to claim 1, further comprising:
a core insulating layer provided along an inner side surface of the semiconductor layer, wherein
the lower surface of the contact plug is in contact with upper surfaces of the core insulating layer and the semiconductor layer.

6. The semiconductor memory device according to claim 1, further comprising:
a third wiring provided above the second wiring in the first direction, wherein
the contact plug is electrically connected to the third wiring.

7. The semiconductor memory device according to claim 1, further comprising:
a third wiring provided above the second wiring in the first direction, wherein
an upper surface of the contact plug is in contact with the third wiring.

8. The semiconductor memory device according to claim 1, wherein
the semiconductor layer includes a first semiconductor region and a second semiconductor region that are arranged with respect to each other in a second direction intersecting the first direction, and an upper surface of the first semiconductor region is lower than an upper surface of the second semiconductor region.

9. The semiconductor memory device according to claim 1, wherein
the semiconductor layer includes a first semiconductor region and a second semiconductor region that are arranged with respect to each other in a second direction intersecting the first direction, the first semiconductor region does not face the second wiring, and the second semiconductor region faces the second wiring.

10. The semiconductor memory device according to claim 1, wherein
in a second direction intersecting the first direction, a width of the second wiring is smaller than a width of the first wiring.

11. The semiconductor memory device according to claim 1, wherein
the contact plug includes tungsten.

12. The semiconductor memory device according to claim 1, wherein
the second wiring includes a plurality of wirings in the first direction, and
the lower surface of the contact plug is in contact with the semiconductor layer above a lower surface of a lowermost wiring among the plurality of wirings.

13. The semiconductor memory device according to claim 1, wherein
a portion of the semiconductor layer in contact with the contact plug does not substantially contain a dopant.

14. The semiconductor memory device according to claim 1, wherein
a dopant concentration of a first portion of the semiconductor layer in contact with the contact plug and a dopant concentration of a second portion of the semiconductor layer facing the first wiring are equal to or less than a detection limit.

15. A method for manufacturing a semiconductor memory device, the method comprising:
forming a first wiring above a substrate in a first direction orthogonal to the substrate;
forming a memory pillar penetrating at least a portion of the first wiring in the first direction;
forming, in the memory pillar, a semiconductor layer extending in the first direction; and
forming a contact plug containing a metal and having a lower surface, in the memory pillar, in contact with the semiconductor layer below an upper surface of the first wiring.

16. The method according to claim 15, further comprising:
forming a core insulating layer provided along an inner side surface of the semiconductor layer, wherein
the lower surface of the contact plug is in contact with an upper surface of the core insulating layer.

17. The method according to claim 15, further comprising:
forming a core insulating layer provided along an inner side surface of the semiconductor layer, wherein
the semiconductor layer includes a first semiconductor layer provided on an upper surface of the core insulating layer, and a second semiconductor layer that covers side surfaces of the core insulating layer and the first semiconductor layer, and
the lower surface of the contact plug is in contact with upper surfaces of the first semiconductor layer and the second semiconductor layer.

18. The method according to claim 15, further comprising:
forming a core insulating layer provided along an inner side surface of the semiconductor layer, wherein
the semiconductor layer includes a first semiconductor layer provided on an upper surface of the core insulating layer, and a second semiconductor layer that covers side surfaces of the core insulating layer, the first semiconductor layer, and the contact plug, and
the lower surface of the contact plug is in contact with an upper surface of the first semiconductor layer.

19. The method according to claim 15, further comprising:
forming a core insulating layer provided along an inner side surface of the semiconductor layer, wherein
the lower surface of the contact plug is in contact with upper surfaces of the core insulating layer and the semiconductor layer.
